(19) United States
(12) Patent Application Publication
(10) Pub. No.: US 2019/0295914 A1
(43) Pub. Date: Sep. 26, 2019

(54) SEMICONDUCTOR DEVICE PACKAGE AND A METHOD OF MANUFACTURING THE SAME

(71) Applicant: Advanced Semiconductor Engineering, Inc., Kaohsiung (TW)

(72) Inventors: Yung-Hsing CHANG, Kaohsiung (TW); Chun-Hsiung CHEN, Kaohsiung (TW); Yung-Chi CHEN, Kaohsiung (TW)

(73) Assignee: Advanced Semiconductor Engineering, Inc., Kaohsiung (TW)

(21) Appl. No.: 15/934,582

(22) Filed: Mar. 23, 2018

(51) Int. Cl. H01L 23/31; B81B 7/00; H01L 23/00; H01L 23/29; H01L 21/56; B81C 1/00

(52) U.S. Cl. CPC H01L 23/3121; B81B 2207/012; H01L 24/48; H01L 23/3185; H01L 23/295; H01L 21/565; B81C 1/0023; H01L 2224/48091; H01L 2924/2064; H01L 2924/1431; H01L 2924/1461; H01L 2224/48225; H01L 2224/48106; H01L 24/32; H01L 2224/32225; H01L 24/73; H01L 2224/73265; H01L 2924/1433; B81B 7/0074

(57) ABSTRACT

A semiconductor device package includes a carrier, a first semiconductor device disposed on the carrier, a second semiconductor device disposed on the first semiconductor device, a conductive wire electrically connecting the first semiconductor device to the carrier, and an encapsulant encapsulating the first semiconductor device, the second semiconductor device and the conductive wire. The second semiconductor device defines a hole. The encapsulant exposes the hole. An apex of the conductive wire is lower than a surface of the second semiconductor device by a first distance (s). The apex of the conductive wire is spaced from the first surface of the encapsulant by a second distance (t). A first surface of the encapsulant is lower than a surface of the second semiconductor device by a third distance (D). The third distance is less than or equal to a difference between the first distance and the second distance.

### BACKGROUND

### 1. Technical Field

The present disclosure relates to a semiconductor device package including an encapsulant and a semiconductor device, a surface of the encapsulant being lower than a surface of the semiconductor device.

### 2. Description of the Related Art

A semiconductor device package may include a semiconductor device defining a hole (or media port). During a process of manufacturing the semiconductor device package, packaging material (e.g. molding compound/encapsulant) or other contaminants may flow into the hole.

### SUMMARY

In some embodiments, according to one aspect, a semiconductor device package includes a carrier, a first semiconductor device disposed on the carrier, a second semiconductor device disposed on the first semiconductor device, a conductive wire electrically connecting the first semiconductor device to the carrier, and an encapsulant encapsulating the first semiconductor device, the second semiconductor device and the conductive wire. The second semiconductor device defines a hole, and has a surface. The encapsulant exposes the hole of the second semiconductor device, and has a first surface. An apex of the conductive wire is lower than the surface of the second semiconductor device by a first distance (s). The conductive wire is spaced from the first surface of the encapsulant by a second distance (t). The first surface of the encapsulant is lower than the surface of the second semiconductor device by a third distance (D). The third distance is less than or equal to a difference between the first distance and the second distance.

In some embodiments, according to another aspect, a semiconductor device package includes a carrier, a first semiconductor device disposed on the carrier, a second semiconductor device disposed on the first semiconductor device, having a surface and a sidewall, and defining a hole, and an encapsulant encapsulating the first semiconductor device and the second semiconductor device, having a first surface, and exposing the hole of the second semiconductor device. The encapsulant includes an inclined portion adjacent to the sidewall of the second semiconductor device. The first surface of the encapsulant is lower than the a surface of the second semiconductor device by a first distance. The first distance is greater than or equal to 22 μm.

In some embodiments, according to another aspect, a method is disclosed for manufacturing a semiconductor device package. The method includes: providing a semiconductor device module, the semiconductor device module including a carrier, a first semiconductor device disposed on the carrier, and a second semiconductor device disposed on the first semiconductor device, having a sidewall, and defining a hole; providing a mold chase on which a film is disposed; moving the mold chase such that the film covers the hole of the second semiconductor device and the sidewall of the second semiconductor device; encapsulating the first semiconductor device and the second semiconductor device with an encapsulant; and removing the mold chase to expose the hole of the second semiconductor device and the sidewall of the second semiconductor device.

In some embodiments, according to another aspect, a method is disclosed for manufacturing a semiconductor device package. The method includes: providing a semiconductor device module, the semiconductor device module including a carrier, a first semiconductor device disposed on the carrier, and a second semiconductor device disposed on the first semiconductor device, the second semiconductor device defining a hole; determining a pressure parameter; determining a distance between a surface of the second semiconductor device and a surface of the carrier; determining a film thickness based on the pressure parameter and the distance; disposing a film having the film thickness on a mold chase; and encapsulating the first semiconductor device and the second semiconductor device using the mold chase.

### BRIEF DESCRIPTION OF THE DRAWINGS

FIG. 1A illustrates a cross-sectional view of a semiconductor device package according to some embodiments of the present disclosure.

FIG. 1B illustrates a cross-sectional view of a semiconductor device package according to some embodiments of the present disclosure.

FIG. 2A illustrates a method of manufacturing a semiconductor device package according to some embodiments of the present disclosure.

FIG. 2B illustrates a method of manufacturing a semiconductor device package according to some embodiments of the present disclosure.

FIG. 2C illustrates a method of manufacturing a semiconductor device package according to some embodiments of the present disclosure.

FIG. 2D illustrates a method of manufacturing a semiconductor device package according to some embodiments of the present disclosure.

FIG. 2E illustrates a method of manufacturing a semiconductor device package according to some embodiments of the present disclosure.

FIG. 3A illustrates a cross-sectional view of a comparative semiconductor device package.

FIG. 3B illustrates a cross-sectional view of a comparative semiconductor device package.

FIG. 4 illustrates a cross-sectional view of a comparative semiconductor device package.

FIG. 5A illustrates a cross-sectional view of a comparative semiconductor device package.

FIG. 5B illustrates a cross-sectional view of a comparative semiconductor device package.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are specified with respect to a certain component or group of components, or a certain plane of a component or group of components, for the orientation of the component(s) as shown in the associated figure. It should be understood that the spatial descriptions used herein are for purposes of illustration only, and that practical implementations of the structures described herein can be spatially arranged in any orientation or manner, provided that the merits of embodiments of this disclosure are not deviated from by such arrangement.

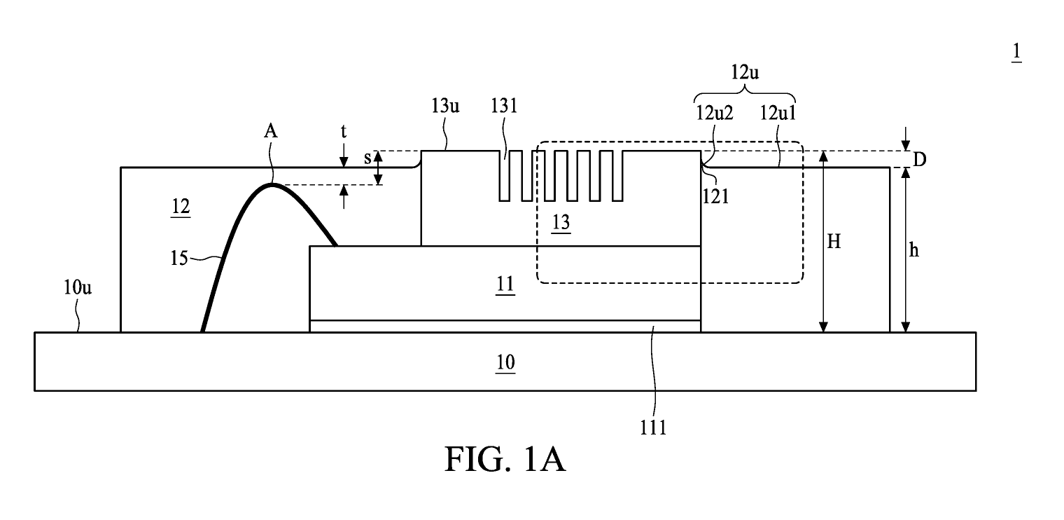

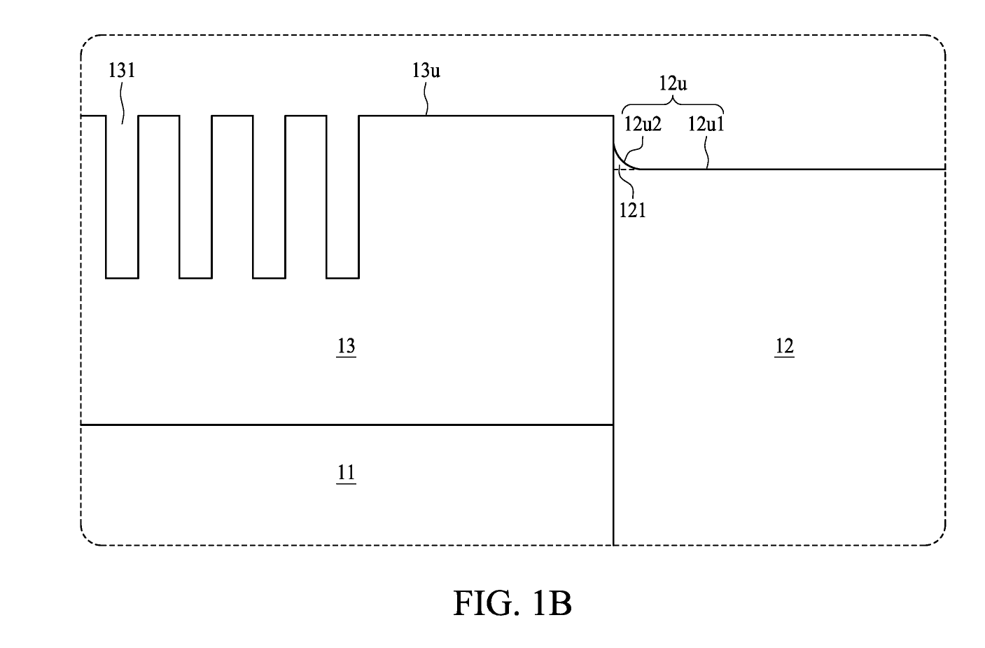

FIG. 1 is a cross-sectional view of a semiconductor device package 1 in accordance with some embodiments of the present disclosure. The semiconductor device package 1 includes a carrier 10 having an upper surface 10u, a semiconductor device 11, an encapsulant 12 having an upper surface 12u, a semiconductor device 13 having an upper surface 13u, and a conductive wire 15. In some embodiments, the carrier 10 may include an organic substrate or a leadframe.

The semiconductor device 11 is disposed on the carrier 10 via an adhesive layer 111. The semiconductor device 11 may include a logical die, such as an application-specific integrated circuit (ASIC). The semiconductor device 11 is electrically connected to the carrier 10 through the conductive wire 15.

The semiconductor device 13 is disposed on the semiconductor device 11. The semiconductor device 13 may include a Micro Electro Mechanical System (MEMS) die. In some embodiments, the semiconductor device 13 may be a MEMS sensor, such as a motion sensor, a chemical sensor, an electrochemical sensor, an environment sensor, or a biomedical sensor. The semiconductor device 13 is electrically connected to the semiconductor device 11. The semiconductor device 13 may be disposed on the semiconductor device 11 (e.g. directly disposed on the semiconductor device 11). The semiconductor device 13 defines a hole 131. The hole 131 is defined by the upper surface 13u of the semiconductor device 13. The semiconductor device 13 may define a plurality of holes including the hole 131.

The upper surface 12u of the encapsulant 12 includes a plane surface 12u1 and a curved surface 12u2. The surface 12u2 of the encapsulant 12 is higher than the surface 12u1 of the encapsulant. The encapsulant 12 is disposed on the carrier 10. The encapsulant includes a resin and a filler. The encapsulant 12 encapsulates the semiconductor device 11, the semiconductor device 13, and the conductive wire 15. A portion of the semiconductor device 13 is exposed from the encapsulant 12. The hole 131 is exposed from the encapsulant 12. The encapsulant 12 includes an inclined portion 121 (e.g. having the upper surface 12u as a top surface). The inclined portion 121 is adjacent to a sidewall of the semiconductor device 13.

The plane surface 12u1 of the encapsulant 12 is lower (e.g. closer to the substrate 10) than the upper surface 13u of the semiconductor device 13 by a distance (D). The upper surface 13u of the semiconductor device 13 is spaced from the upper surface 10u of the carrier 10 by a distance (H). The plane surface 12u1 of the encapsulant 12 is spaced from the upper surface 10u of the carrier 10 by a distance (h). The distance D is substantially equal to a difference between the distance H and the distance h. A turning point (A) of the conductive wire 15 is lower (e.g. closer to the substrate 10) than the upper surface 13u of the semiconductor device 13 by a distance (s). The turning point A is an apex of the conductive wire 15 (e.g. a peak or highest point). The point A of the conductive wire 15 is spaced from the plane surface 12u1 of the encapsulant 12 by a distance (t).

The distance D is less than or about equal to a difference between the distance s and the distance t (e.g. the distance D is about 0.95 times or less the difference between the distance s and the distance t, is about 0.90 times or less the difference between the distance s and the distance t, or is about 0.85 times or less the difference between the distance s and the distance t). The distance D is greater than or equal to about 22 micrometers (μm). In some embodiments, the distance D is in a range from approximately 22 μm to approximately 65 μm. The distance s is less than or equal to about 75 μm (e.g. is about 72 μm or less, is about 69 μm or less, or is about 66 μm or less). The distance t is greater than or equal to about 5 μm (e.g. is about 6 μm or more, about 7 μm or more, or about 8 μm or more).

FIG. 1B is a cross-sectional view of a semiconductor device package in accordance with some embodiments of the present disclosure, and shows an enlarged view of a region delimited by a dashed line in FIG. 1A. The encapsulant 12 has the upper surface 12u. The upper surface 12u of the encapsulant 12 includes the plane surface 12u1 and the curved surface 12u2.

The encapsulant 12 includes the inclined portion 121. The inclined portion 121 surrounds the sidewall of the semiconductor device 13. The inclined portion 121 covers a first portion of the sidewall of the semiconductor device 13. A second portion of the sidewall of the semiconductor device 13 is exposed from the inclined portion 121. The inclined portion 121 has the surface 12u2.

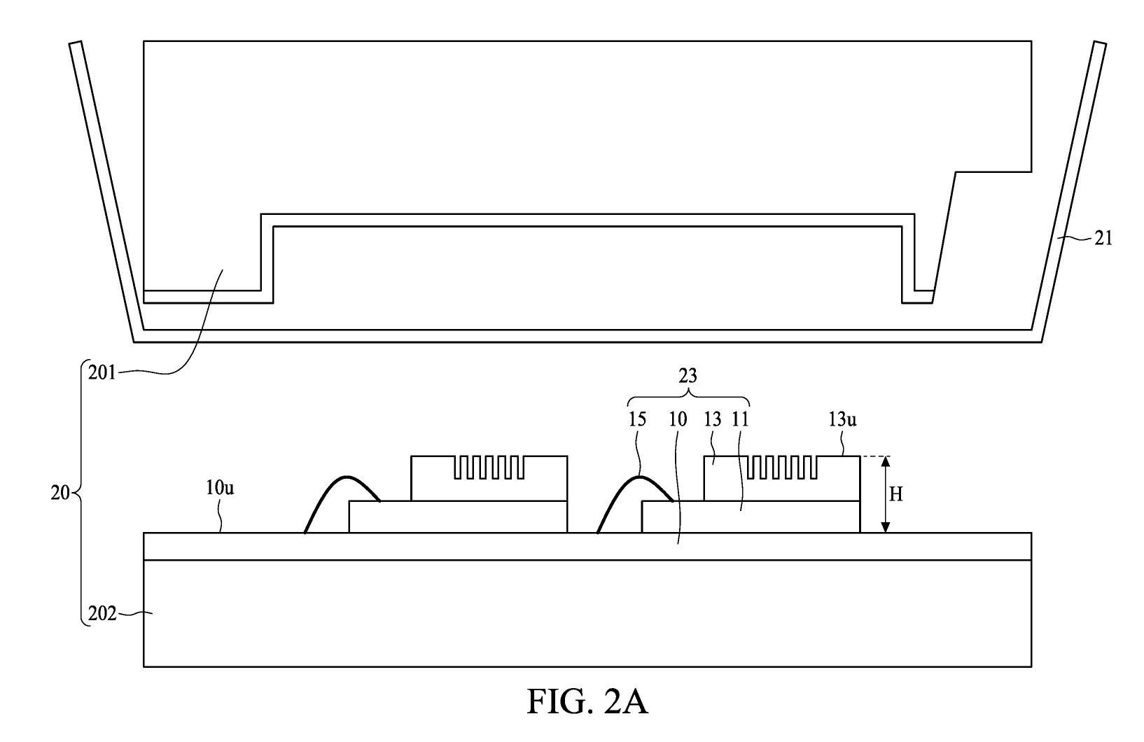

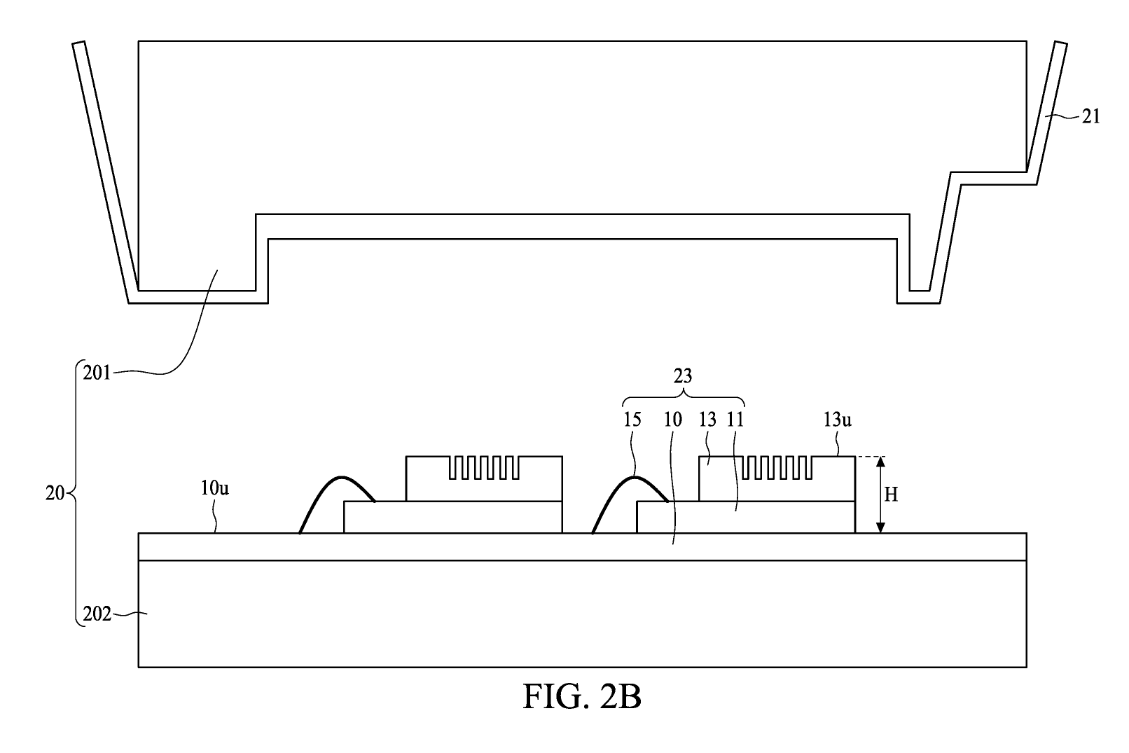

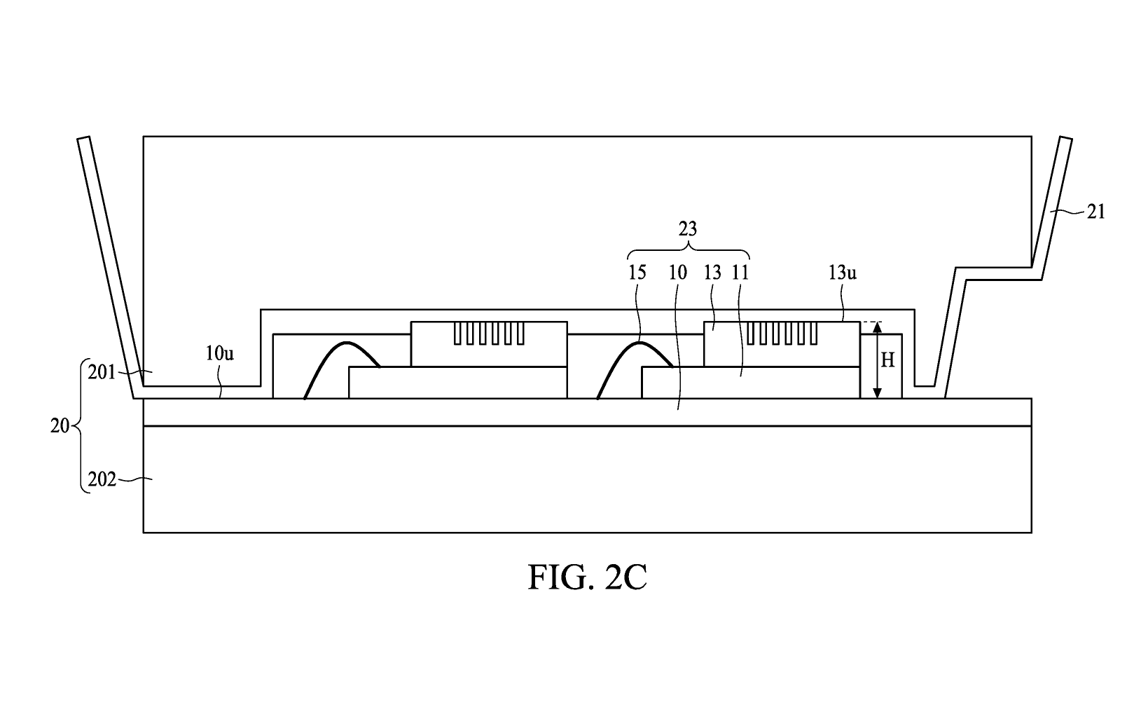

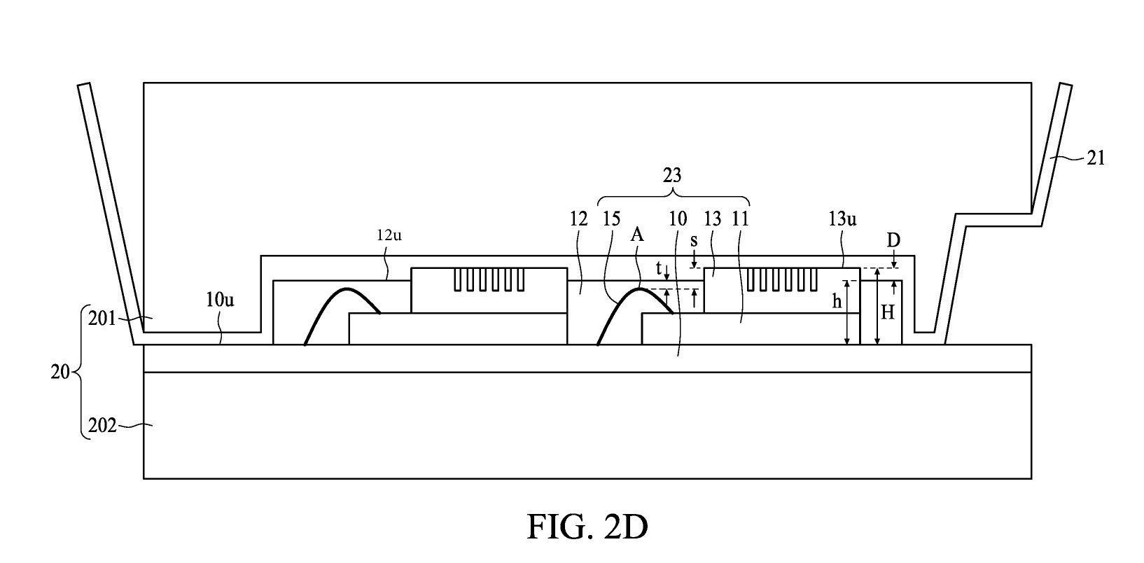

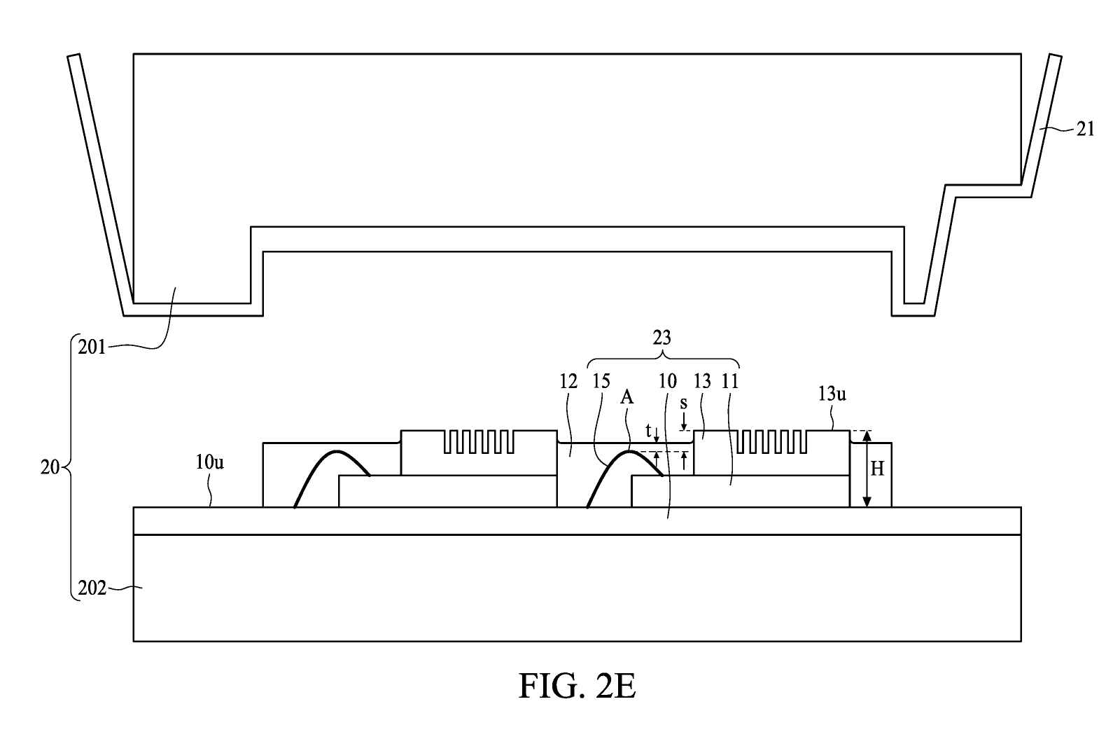

FIG. 2A through FIG. 2E illustrate some embodiments of a method of manufacturing the semiconductor device package 1 according to some embodiments of the present disclosure.

Referring to FIG. 2A, a method for manufacturing the semiconductor device package 1 includes providing or assembling a semiconductor device module 23. The semiconductor device module 23 includes a carrier 10 having an upper surface 10u, a semiconductor device 11, a semiconductor device 13 having an upper surface 13u, and a conductive wire 15. The semiconductor device 11 is disposed on the carrier 10 via an adhesive layer 111 (not shown in FIG. 2A). In some embodiments, a plurality of semiconductor device modules 23 can be disposed adjacently (e.g. in a row), and the plurality of semiconductor device modules 23 can share a carrier 10. The semiconductor device 11 is electrically connected to the carrier 10 through the conductive wire 15. The semiconductor device 11 may include a logical die. The semiconductor device 13 is electrically connected to the semiconductor device 11. The semiconductor device 13 defines a hole 131. The hole 131 is defined by the upper surface 13u of the semiconductor device 13. The semiconductor device 13 may include a MEMS die.

During a molding operation (e.g. a molding operation described herein), a molding chase 20 can be used, and a computing apparatus can be used for determining a clamp pressure parameter of the molding chase 20. The computing apparatus may include a processor and machine-readable instructions that, when executed by the processor, cause the processor to perform processes described herein. The computing apparatus can be used to determine a transfer pressure parameter of the molding chase 20. The clamp pressure parameter may have a value in a range from approximately 85 tons to approximately 100 tons, or from approximately 20662 kilopascal (kpa) to approximately 24308 kpa. The transfer pressure parameter may have a value in a range from approximately 0.7 tons to approximately 0.8 tons or from approximately 5148 kpa to approximately 5884 kpa. A distance (H) between the upper surface 13u of the semiconductor device 13 and the upper surface 10u of the carrier 10 can be selected according to design specifications. A film 21 may be provided, and may be disposed between the molding chase and the semiconductor module 23. A thickness of a film 21 is determined (e.g. determined and selected) based on the determined clamp pressure parameter and the distance H. A thickness of the film 21 may be greater than or equal to approximately 125 μm. In some embodiments, the film 21 has a thickness in a range from approximately 25 μm to approximately 200 μm. The film 21 includes a single material. The film 21 may include Teflon. The film 21 may include a single layer structure (e.g. as compared to a film that includes both a base layer and a release layer).

The semiconductor device module 23 is provided on the molding chase 20. The molding chase 20 includes a portion 201 and a portion 202. The semiconductor device module 23 may be provided on the portion 202 of the molding chase 20 via an adhesive. The film 21 is provided adjacent to the portion 201 of the molding chase 20.

Referring to FIG. 2B, the film 21 is disposed on the portion 201 of the molding chase 20 (e.g. directly on the portion 201 of the molding chase 20. The film 21 may be pressed into the portion 201 of the molding chase 20 such that the film 21 conforms to a surface of the portion 201 of the molding chase 20.

Referring to FIG. 2C, the portion 201 is pressed to the portion 202 using pressure applied by a clamp. The film 21 is pressed to the carrier 10 and the semiconductor device module 23. The film 21 covers the upper surface 13u of the semiconductor device 13. The film 21 covers the hole 131. The portion 201 of the molding chase 21 covers the hole 131. The pressure applied by the clamp may cause the film 21 to be pushed beyond the upper surface 13u of the semiconductor device 13.

Referring to FIG. 2D, the semiconductor device module 23 is subject to a transfer pressure by the mold chase 20 during the molding operation. The semiconductor device 11, the semiconductor device 13, and the conductive wire 15 are encapsulated by an encapsulant 12. The encapsulant 12 has an upper surface 12u. The upper surface 12u of the encapsulant 12 is lower (e.g. closer to the substrate 10) than the upper surface 13u of the semiconductor device 13 by a distance (D). The distance D is greater than or equal to about 22 μm. In some embodiments, the distance D is in a range from approximately 22 μm to approximately 65 μm.

In one or more embodiments, when the clamp pressure is approximately 85 tons and the transfer pressure is approximately 0.7 tons, the distance D is in a range from approximately 22 μm to approximately 40 μm. When the clamp pressure is approximately 100 tons and the transfer pressure is approximately 0.8 tons, the distance D is in a range from approximately 50 μm to approximately 65 μm.

The upper surface 12u of the encapsulant 12 is spaced from the upper surface 10u of the carrier 10 by a distance (h). The distance D is equal to a difference between the distance H and the distance h. A turning point (A) of the conductive wire 15 is spaced from the upper surface 12u of the encapsulant 12 by a distance (t). The distance t may help to ensure that the conductive wire 15 would not be exposed from the encapsulant 12 during a subsequent laser marking operation. The encapsulant 12 which covers the conductive wire 15 may protect the conductive wire 15 from damage in subsequent operation(s). The turning point A is an apex of the conductive wire 15. The turning point A of the conductive wire 15 is spaced from the upper surface 13u of the semiconductor device 13 by a distance (s). The distance s is less than or equal to about 75 μm (e.g. is about 72 μm or less, is about 69 μm or less, or is about 66 μm or less). The distance t is greater than or equal to about 5 μm (e.g. is about 6 μm or more, about 7 μm or more, or about 8 μm or more).

The film 21 can help to prevent a molding compound bleeding into the hole 131 during the molding operation. The film 21 can help to prevent the hole 131 being damaged by the molding chase 20 when the portion 201 is pressed to the portion 202. Using the computing apparatus, a thickness of the film 21 can be selected such that the conductive wire 15 is not pressed by the molding chase 20, and/or such that the conductive wire 15 is not in contact with the molding chase 20 during the molding operation.

Referring to FIG. 2E, the molding chase 20 is removed to expose the hole 131 of the semiconductor device 13 and the sidewall of the semiconductor device 13. In one or more embodiments the film 21 is a single layer structure and/or includes Teflon, which provides for ready removal of the film 21 such that the film is not left covering the hole 131 of the semiconductor device 13. Subsequently, the semiconductor device package 1 could be formed during a singulation operation.

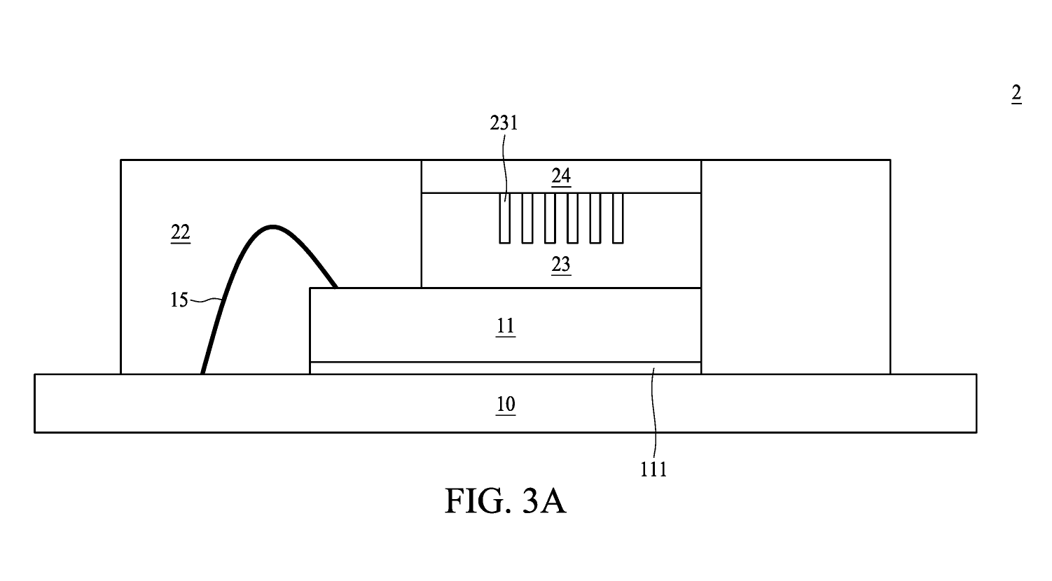

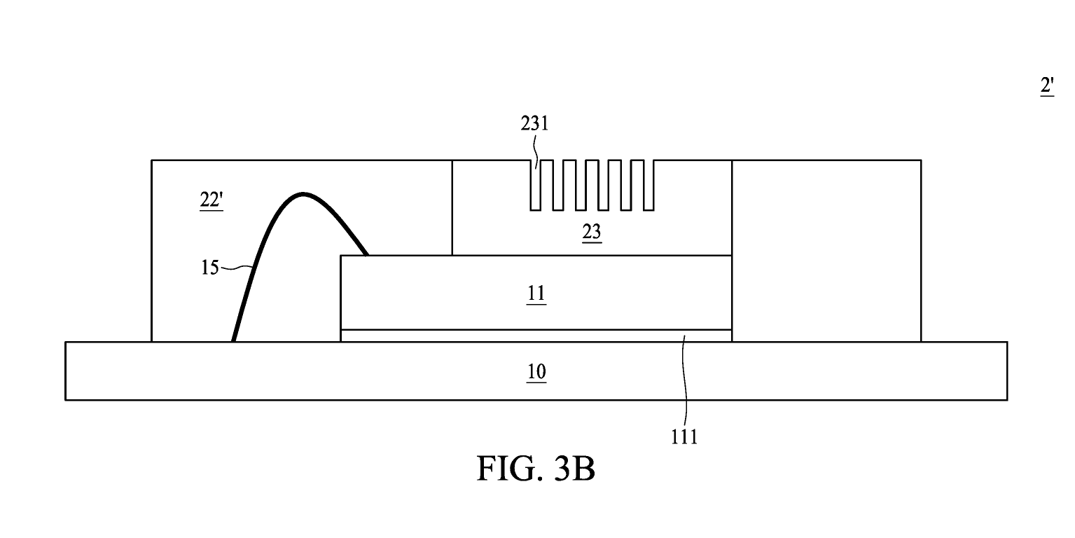

FIG. 3A is a cross-sectional view of a comparative semiconductor device package 2. The semiconductor device package 2 includes a carrier 10, a semiconductor device 11, an encapsulant 22, a semiconductor device 23, a dielectric layer 24, and a conductive wire 15.

The semiconductor device 11 is disposed on the carrier 10 via an adhesive layer 111. The semiconductor device 11 may include a logical die, such as an application-specific integrated circuit (ASIC). The semiconductor device 11 is electrically connected to the carrier 10 through the conductive wire 15.

The semiconductor device 23 is disposed on the semiconductor device 11. The semiconductor device 23 may include a MEMS die. The semiconductor device 23 is electrically connected to the semiconductor device 11. The semiconductor device 23 defines a hole 231. The hole 231 is covered by the dielectric layer 24. A material of the dielectric layer 24 may be the same as the material of the encapsulant 22. The dielectric layer 24 and the encapsulant 22 may be formed during an over-molding operation. The dielectric layer 24 and the encapsulant 22 may be formed at the same time.

The material of the dielectric layer 24 may bleed into the hole 231. Additionally, the material of the encapsulant 22 may also bleed into the hole 231 during the over-molding operation.

FIG. 3B is a cross-sectional view of a comparative semiconductor device package 2′. The structure of the semiconductor device package 2′ of FIG. 3B is similar to the structure of semiconductor device package 2 of FIG. 3A, except that a hole 231 of a semiconductor device 23 is exposed from an encapsulant 22′ and is not covered by the dielectric layer 24. The dielectric layer 24 and an upper portion of the encapsulant 22 may be removed during a grinding operation.

However, the hole 231 of the semiconductor device 23 may be damaged during the grinding operation. Additionally, the hole 231 may be contaminated during the grinding operation (e.g. contaminants such as pieces of the dielectric layer 24 may fall into the hole 231).

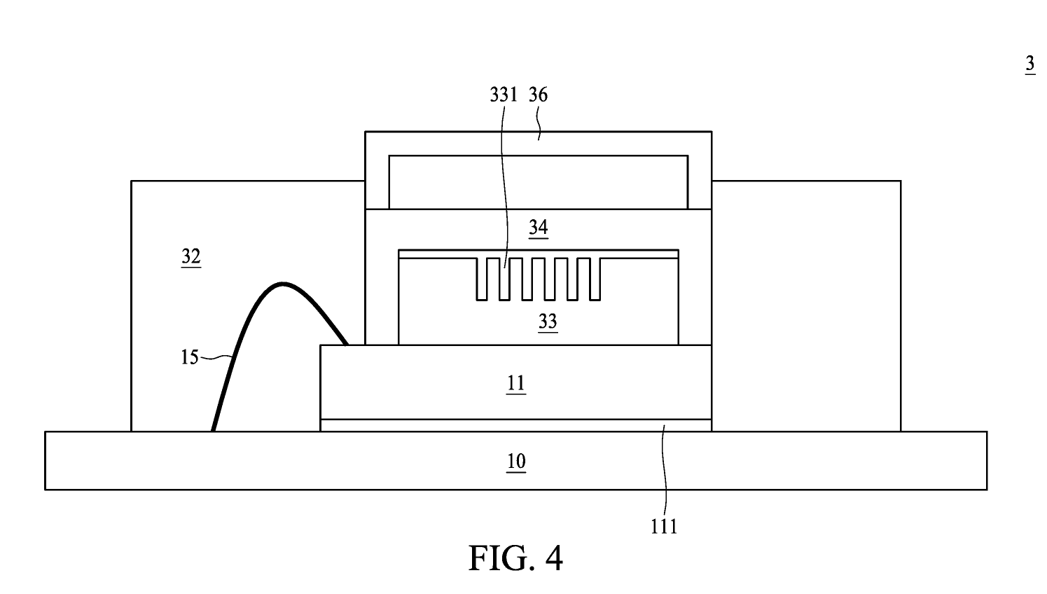

FIG. 4 is a cross-sectional view of a comparative semiconductor device package 3. The semiconductor device package 3 includes a carrier 10, a semiconductor device 11, an encapsulant 32, a semiconductor device 33, a dielectric layer 34, a conductive wire 15, and a capping element 36.

The semiconductor device 11 is disposed on the carrier 10 via an adhesive layer 111. The semiconductor device 11 may include a logical die, such as an application-specific integrated circuit (ASIC). The semiconductor device 11 is electrically connected to the carrier 10 through the conductive wire 15.

The semiconductor device 33 is disposed on the semiconductor device 11. The semiconductor device 33 may include a MEMS die. The semiconductor device 33 is electrically connected to the semiconductor device 11. The semiconductor device 33 defines a hole 331. The hole 331 is covered by the dielectric layer 34. The material of the dielectric layer 34 may be different from or the same as the material of the encapsulant 32. The dielectric layer 34 is disposed on the carrier 10. The dielectric layer 34 covers the semiconductor device 33. The dielectric layer 34 surrounds the semiconductor device 33. There is a space between the semiconductor device 33 and the dielectric layer 34. The hole 331 is spaced from the dielectric layer 34 by the space. The hole 331 is protected to some degree by the dielectric layer 34 (e.g. from contaminants). The capping element 36 is disposed on the dielectric layer 34. The capping element 36 is disposed over the semiconductor device 33. The semiconductor device 33 may be protected to some degree by the dielectric layer 34 and the capping element 36. However, the manufacturing operations of the semiconductor device package 3 may be complicated. Also, costs of the manufacturing operations may be high.

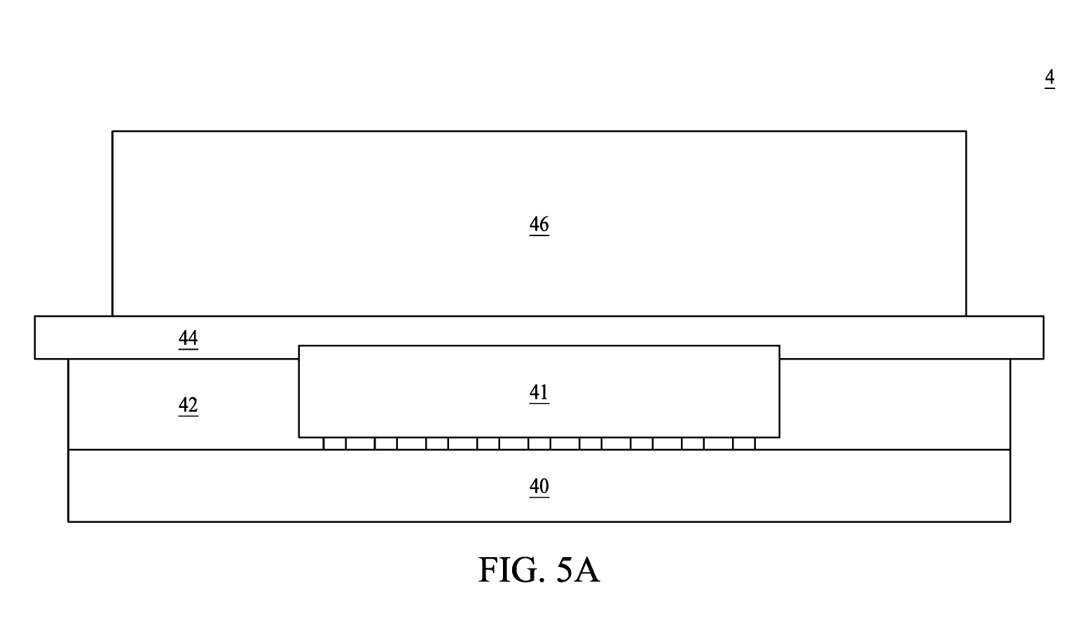

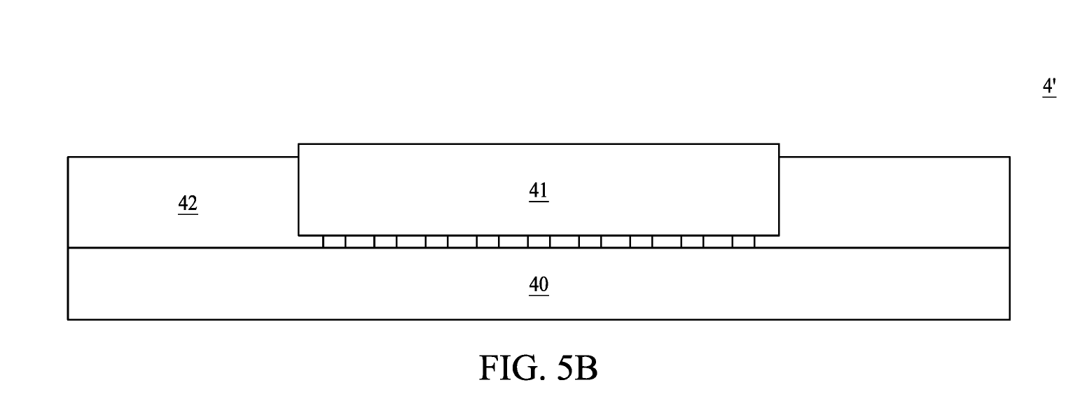

FIG. 5A is a cross-sectional view of a comparative semiconductor device package 4 during a molding operation. The semiconductor device package 4 includes a carrier 40, a semiconductor device 41, and an encapsulant 42.

The semiconductor device 41 is pressed by a film 44 and a molding chase 46 during the molding operation. The semiconductor device 41 is encapsulated by the encapsulant 42 during the molding operation. The semiconductor device 41 may be an integrated circuit (IC) device.

The film 44 is a two-layer structure. The film 44 includes a base layer and a release layer. The base layer has a thickness in a range from approximately 25 μm to approximately 45 μm. The release layer has a thickness in a range from approximately 3 μm to approximately 25 μm. When removing the film 44, the release layer may be left over the semiconductor device 41 (e.g. covering the semiconductor device 41).

FIG. 5B is a cross-sectional view of a comparative semiconductor device package 4′. The semiconductor device package 4′ includes a carrier 40, a semiconductor device 41, and an encapsulant 42.

The semiconductor device 41 is disposed on the carrier 40. The semiconductor device 41 is electrically connected to the carrier 40 via a plurality of connection elements instead of a conductive wire. The connection elements may be conductive pads. The semiconductor device 41 may be an IC device. The semiconductor device 41 is encapsulated by the encapsulant 42.

As used herein and not otherwise defined, the terms “substantially,” “substantial,” “approximately” and “about” are used to describe and account for small variations. When used in conjunction with an event or circumstance, the terms can encompass instances in which the event or circumstance occurs precisely as well as instances in which the event or circumstance occurs to a close approximation. For example, when used in conjunction with a numerical value, the terms can encompass a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. The term “substantially coplanar” can refer to two surfaces within micrometers of lying along a same plane, such as within 40 μm, within 30 μm, within 20 μm, within 10 μm, or within 1 μm of lying along the same plane.

As used herein, the singular terms “a,” “an,” and “the” may include plural referents unless the context clearly dictates otherwise. In the description of some embodiments, a component provided “on” or “over” another component can encompass cases where the former component is directly on (e.g., in physical contact with) the latter component, as well as cases where one or more intervening components are located between the former component and the latter component.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not necessarily be drawn to scale. There may be distinctions between the artistic renditions in the present disclosure and the actual apparatus due to manufacturing processes and tolerances. There may be other embodiments of the present disclosure which are not specifically illustrated. The specification and the drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations.

What is claimed is:

1. A semiconductor device package, comprising:
a carrier;
a first semiconductor device disposed on the carrier;
a second semiconductor device disposed on the first semiconductor device and having a surface, the second semiconductor device defining a hole;
a conductive wire electrically connecting the first semiconductor device to the carrier; and
an encapsulant encapsulating the first semiconductor device, the second semiconductor device and the conductive wire, the encapsulant having a first surface, and exposing the hole of the second semiconductor device,
wherein an apex of the conductive wire is lower than the surface of the second semiconductor device by a first distance, the apex of the conductive wire is spaced from the first surface of the encapsulant by a second distance, and the first surface of the encapsulant is lower than the surface of the second semiconductor device by a third distance, and
wherein the third distance is less than or equal to a difference between the first distance and the second distance.

2. The semiconductor device package of claim 1, wherein the third distance is greater than or equal to approximately 22 μm.

3. The semiconductor device package of claim 2, wherein the third distance is in a range from approximately 22 μm to approximately 65 μm.

4. The semiconductor device package of claim 1, wherein the first distance is less than or equal to approximately 75 μm.

5. The semiconductor device package of claim 1, wherein the second distance is greater than or equal to approximately 5 μm.

6. The semiconductor device package of claim 1, wherein the encapsulant comprises an inclined portion, the second semiconductor device has a sidewall, and a portion of the sidewall of the second semiconductor device is exposed from the inclined portion of the encapsulant.

7. The semiconductor device package of claim 6, wherein the inclined portion of the encapsulant has a second surface, and wherein the second surface of the inclined portion of the encapsulant is higher than the first surface of the encapsulant.

8. The semiconductor device package of claim 1, wherein the encapsulant comprises a resin and a filler.

9. The semiconductor device package of claim 1, wherein the first semiconductor device is a logical die.

10. The semiconductor device package of claim 1, wherein the second semiconductor device is a microelectromechanical system (MEMS) die.

11. A semiconductor device package, comprising:
a carrier;
a first semiconductor device disposed on the carrier;
a second semiconductor device disposed on the first semiconductor device, the second semiconductor device having a surface and a sidewall, and defining a hole; and
an encapsulant encapsulating the first semiconductor device and the second semiconductor device, having a first surface, and exposing the hole of the second semiconductor device, the encapsulant comprising an inclined portion adjacent to the sidewall of the second semiconductor device,
wherein the first surface of the encapsulant is lower than the surface of the second semiconductor device by a first distance, and
wherein the first distance is greater than or equal to approximately 22 μm.

12. The semiconductor device package of claim 11, wherein the first distance is in a range from approximately 22 μm to approximately 65 μm.

13. The semiconductor device package of claim 11, further comprising a conductive wire electrically connecting the first semiconductor device to the carrier.

14. The semiconductor device package of claim 13, wherein an apex of the conductive wire is lower than the surface of the second semiconductor device by a second distance, and wherein the second distance is less than or equal to approximately 75 μm.

15. The semiconductor device package of claim 14, wherein the apex of the conductive wire is spaced from the first surface of the encapsulant by a third distance, and wherein the third distance is greater than or equal to approximately 5 μm.

16. The semiconductor device package of claim 11, wherein the inclined portion covers at least a portion of the sidewall of the second semiconductor device.

17. The semiconductor device package of claim 11, wherein the first semiconductor device is a logical die.

18. The semiconductor device package of claim 11, wherein the second semiconductor device is a MEMS die.

19. A method for manufacturing a semiconductor device package, comprising:
providing a semiconductor device module, the semiconductor device module comprising:
a carrier;
a first semiconductor device disposed on the carrier, and
a second semiconductor device disposed on the first semiconductor device, having a sidewall and defining a hole;
providing a mold chase on which a film is disposed;
moving the mold chase such that the film covers the hole of the second semiconductor device and the sidewall of the second semiconductor device;
encapsulating the first semiconductor device and the second semiconductor device with an encapsulant; and
removing the mold chase to expose the hole of the second semiconductor device and the sidewall of the second semiconductor device.

20. The method of claim 19, wherein the semiconductor device module further comprises a conductive wire electrically connecting the first semiconductor device to the carrier.

21. The method of claim 19, wherein the second semiconductor device has a surface, and the encapsulating is performed such that the encapsulant has a first surface lower than the surface of the second semiconductor device by a first distance in a range from approximately 22 μm to approximately 65 μm.

22. The method of claim 21, wherein moving the mold chase comprises having the mold chase apply a pressure, wherein the pressure is in a range from approximately 85 tons to approximately 100 tons.

23. The method of claim 21, wherein the first distance is in a range from approximately 50 μm to approximately 65 μm.

24. The method of claim 21, wherein the first distance is in a range from approximately 22 μm to approximately 40 μm.

25. The method of claim 19, wherein the film has a thickness in a range from approximately 25 μm to approximately 200 μm.

26. A method for manufacturing a semiconductor device package, comprising:
providing a semiconductor device module, the semiconductor device module comprising:
a carrier;
a first semiconductor device disposed on the carrier; and
a second semiconductor device disposed on the first semiconductor device, the second semiconductor device defining a hole;
determining a pressure parameter;
determining a distance between a surface of the second semiconductor device and a surface of the carrier;
determining a film thickness based on the pressure parameter and the distance;
disposing a film having the film thickness on a mold chase; and
encapsulating the first semiconductor device and the second semiconductor device using the mold chase.
